(19) United States
(12) Patent Application Publication
(10) Pub. No.: US 2018/0286835 A1
(43) Pub. Date: Oct. 4, 2018

(54) SEMICONDUCTOR PACKAGES AND METHODS OF MANUFACTURING THE SAME

(71) Applicant: SK hynix Inc., Icheon-si (KR)

(72) Inventor: Da Un NAH, Seongnam-si (KR)

(73) Assignee: SK hynix Inc., Icheon-si (KR)

(21) Appl. No.: 15/812,638

(22) Filed: Nov. 14, 2017

(30) Foreign Application Priority Data
Apr. 3, 2017 (KR) 10-2017-0043267

(51) Int. Cl. H01L 25/065; H01L 25/00; H01L 23/00; H01L 21/78; H01L 21/683

(52) U.S. Cl. CPC H01L 25/0657; H01L 2221/68327; H01L 24/16; H01L 24/81; H01L 21/78; H01L 21/6836; H01L 2225/06513; H01L 2225/06541; H01L 2225/06555; H01L 2225/06582; H01L 2224/16146; H01L 2224/81024; H01L 2224/81815; H01L 2924/1436; H01L 2924/3511; H01L 25/50

(57) ABSTRACT

There may be provided a method of manufacturing a semiconductor package. The method may include forming a plurality of stack structures on a wafer to be laterally spaced apart from each other. Each of the plurality of stack structures may include core dies vertically stacked. An underfill layer may be formed on the wafer to fill gaps between the plurality of stack structures. A portion of the underfill layer and a portion of the wafer may be removed to provide stack cubes separated from each other. The stack cubes may be mounted side-by-side on a base die wafer. A mold layer may be formed on the base die wafer to fill spaces between the stack cubes. Related semiconductor packages may also be provided.

### CROSS-REFERENCE TO RELATED APPLICATIONS

The present application claims priority under 35 U.S.C 119(a) to Korean Application No. 10-2017-0043267, filed on Apr. 3, 2017, which is incorporated herein by references in its entirety.

### BACKGROUND

### 1. Technical Field

Embodiments of the present disclosure may generally relate to semiconductor technologies and, more particularly, to semiconductor packages and methods of manufacturing the same.

### 2. Related Art

In the electronics industry, a three-dimensional semiconductor package technique for vertically stacking a plurality of semiconductor dies is increasingly in demand with the development of multi-functional, larger storage capacity of and smaller electronic systems or products. In addition, a high bandwidth memory (HBM) solution technique is in demand to obtain a fast data transmission speed. In response to such a demand, an HBM package has been proposed. The HBM package may be realized to include a plurality of memory dies which are vertically stacked, and the plurality of stacked memory dies may be electrically connected to each other by through silicon vias (TSVs). A lot of effort has been focused on applying a chip-on-wafer process technique to provide for the realization of the HBM packages. In order to employ the chip-on-wafer process technique in the fabrication of the HBM packages, it may be necessary to develop methods of electrically isolating the stacked memory dies from each other and methods of overcoming warpage of base die wafers used in the fabrication of the HBM packages.

### SUMMARY

According to an embodiment, there may be provided a method of manufacturing semiconductor packages. The method may include forming a plurality of stack structures on a wafer to be laterally spaced apart from each other. Each of the plurality of stack structures may include core dies vertically stacked. An underfill layer may be formed on the wafer to fill gaps between the plurality of stack structures. A portion of the underfill layer and a portion of the wafer may be removed to provide stack cubes separated from each other. Each of the stack cubes may include a roof die comprised of a part of the wafer, one of the plurality of stack structures, and an underfill layer pattern comprised of a part of the underfill layer to cover sidewalls of the one of the plurality of stack structures. The stack cubes may be mounted side-by-side on a base die wafer. A mold layer may be formed over the base die wafer to fill spaces between the stack cubes.

According to an embodiment, a semiconductor package may be provided. The semiconductor package may include a plurality of core dies vertically stacked on a base die. The semiconductor package may include a roof die stacked on a stack structure including the plurality of core dies. The semiconductor package may include an underfill layer pattern filling spaces between the core dies and including a fillet portion covering sidewalls of the core dies. The underfill layer pattern may have vertical sidewalls which are aligned with sidewalls of the roof die. A mold layer pattern may be disposed to cover the sidewalls of the underfill layer pattern and the sidewalls of the roof die. The mold layer pattern may have sidewalls, and the sidewalls of the mold layer pattern and the sidewalls of the underfill layer pattern may have substantially the same vertical profile.

According to an embodiment, there may be provided a method of manufacturing semiconductor packages. The method may include forming a plurality of stack structures on a wafer to be laterally spaced apart from each other. Each of the plurality of stack structures may include core dies vertically stacked. A first underfill layer may be formed on the wafer to fill gaps between the plurality of stack structures. A portion of the first underfill layer and a portion of the wafer may be removed to provide stack cubes separated from each other. Each of the stack cubes may include a roof die comprised of a part of the wafer, one of the plurality of stack structures, and a first underfill layer pattern comprised of a part of the first underfill layer to cover sidewalls of the one of the plurality of stack structures. The stack cubes may be mounted side-by-side on a base die wafer. A second underfill layer may be formed to fill spaces between the base die wafer and the stack cubes. A mold layer may be formed over the base die wafer to fill spaces between the stack cubes.

According to an embodiment, a semiconductor package may include a plurality of core dies vertically stacked on a base die. The semiconductor package may include a roof die stacked on a stack structure including the plurality of core dies. The semiconductor package may include a first underfill layer pattern filling spaces between the core dies and including a fillet portion covering sidewalls of the core dies. The first underfill layer pattern may have vertical sidewalls which are aligned with sidewalls of the roof die. A second underfill layer may be disposed to fill a space between the base die and the core die adjacent to the base die. A mold layer pattern may be disposed to cover the sidewalls of the first underfill layer pattern, sidewalls of the second underfill layer, and the sidewalls of the roof die. The mold layer pattern may have sidewalls, and the sidewalls of the mold layer pattern and the sidewalls of the first underfill layer pattern may have substantially the same vertical profile.

### BRIEF DESCRIPTION OF THE DRAWINGS

FIGS. 1 to 7 are cross-sectional views illustrating a method of manufacturing semiconductor packages according to an embodiment.

FIG. 8 is a cross-sectional view illustrating a semiconductor package according to an embodiment.

FIG. 9 is a cross-sectional view illustrating a method of manufacturing semiconductor packages according to an embodiment.

FIG. 10 is a cross-sectional view illustrating a semiconductor package according to an embodiment.

FIG. 11 is a block diagram illustrating an electronic system employing a memory card including at least one of packages according to the embodiments.

FIG. 12 is a block diagram illustrating an electronic system including at least one of packages according to the embodiments.

### DETAILED DESCRIPTION

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong. It will be understood that although the terms first, second, third etc. may be used herein to describe various elements, these elements should not be limited by these terms. These terms are only used to distinguish one element from another element, but not used to define only the element itself or to mean a particular sequence.

Semiconductor packages according to the following embodiments may correspond to stack packages including a plurality of semiconductor dies or a plurality of semiconductor chips which are vertically stacked. The separate semiconductor dies or the separate semiconductor chips may be obtained by separating a semiconductor substrate such as a semiconductor wafer including electronic circuits into a plurality of pieces (having semiconductor die shapes or semiconductor chip shapes) using a die sawing process. Each of the semiconductor dies may include a through silicon via (TSV) structure. The TSV structure may correspond to an interconnection structure including a plurality of through electrodes or a plurality of through vias that vertically penetrate each semiconductor die. The semiconductor dies may correspond to memory dies such as dynamic random access memory (DRAM) dies, static random access memory (SRAM) dies, NAND-type flash memory dies, NOR-TYPE flash memory dies, magnetic random access memory (MRAM) dies, resistive random access memory (ReRAM) dies, ferroelectric random access memory (FeRAM) dies or phase change random access memory (PcRAM) dies. The semiconductor dies or the semiconductor packages may be employed in communication systems such as mobile phones, electronic systems associated with biotechnology or health care, or wearable electronic systems.

The stack package according to an embodiment may be a high bandwidth memory (HBM) package. The HBM package may include an HBM interface to improve a data transmission speed between the HBM package and a processor chip. The HBM interface of the HBM package may be realized using a through-silicon via (TSV) input and output (input/output) (I/O) unit including a plurality of TSVs. A processor chip supporting an operation of the HBM package may be an application specific integrated circuit (ASIC) chip including a central processing unit (CPU) or a graphics processing unit (GPU), a microprocessor or a microcontroller, an application processor (AP), a digital signal processing core, and an interface.

The same reference numerals refer to the same elements throughout the specification. Thus, even though a reference numeral is not mentioned or described with reference to a drawing, the reference numeral may be mentioned or described with reference to another drawing. In addition, even though a reference numeral is not illustrated in a drawing, it may be mentioned or described with reference to another drawing.

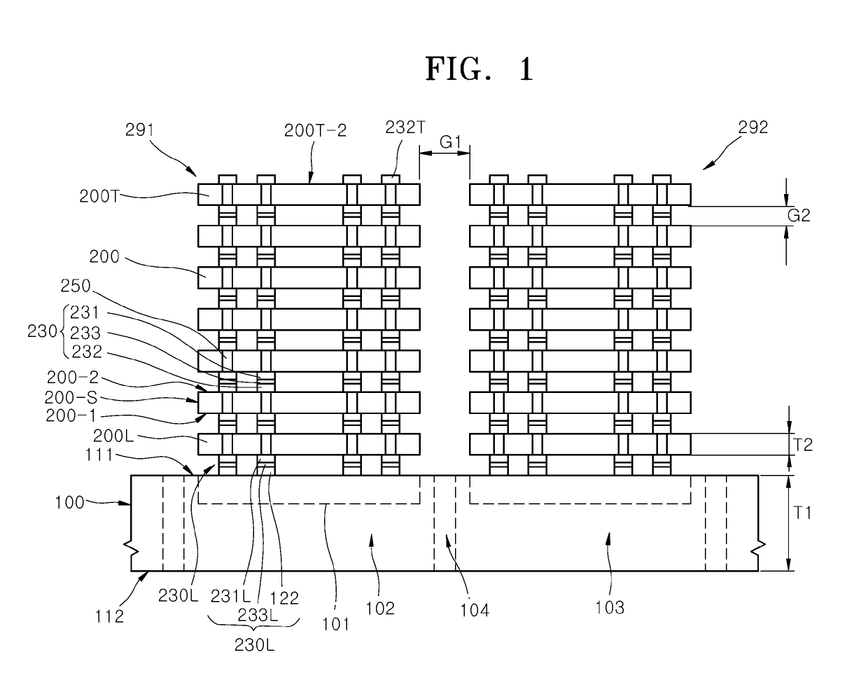

FIG. 1 is a cross-sectional view illustrating core dies 200 stacked on a wafer 100 including first and second roof die regions 102 and 103.

Referring to FIG. 1, the wafer 100 having the first and second roof die regions 102 and 103 may be provided. At least two of the core dies 200 may be vertically stacked on each of the first and second roof die regions 102 and 103. The wafer 100 may be used as a base layer on which the core dies 200 are stacked. The wafer 100 may be a semiconductor wafer. The wafer 100 may be a semiconductor wafer in which a plurality of roof die regions, for example, the first and second roof die regions 102 and 103 are disposed. Each of the first and second roof die regions 102 and 103 may be a semiconductor die region including an integrated region 101 in which an integrated circuit of a first semiconductor device is realized. The first semiconductor device realized in the integrated region 101 may be a memory device such as a DRAM device.

An intermediate region 104 may be disposed between the first and second roof die regions 102 and 103. The intermediate region 104 may include a scribe lane. The first and second roof die regions 102 and 103 may be separated from each other if a die sawing process is performed along the intermediate region 104.

The wafer 100 may have a first surface 111 on which the core dies 200 are stacked and a second surface 112 which is opposite to the core dies 200. The first surface 111 of the wafer 100 may correspond to a front-side surface or a topside surface of the wafer 100, and the second surface 112 of the wafer 100 may correspond to a backside surface or a bottom-side surface of the wafer 100. The wafer 100 may have a thickness T1. The thickness T1 may correspond to a distance between the first surface 111 and the second surface 112.

The thickness T1 of the wafer 100 may be greater than a thickness T2 of each of the core dies 200. The thickness T1 of the wafer 100 may be set to be several times the thickness T2 of each core die 200. Since the thickness T1 of the wafer 100 is relatively greater than the thickness T2 of each core die 200, warpage of the wafer 100 due to a thermal stress may be suppressed in subsequent processes.

Wafer connection terminals 122 may be formed on the first surface 111 of the wafer 100 to electrically connect the wafer 100 to the core dies 200 stacked on the wafer 100. The wafer connection terminals 122 may be formed of bumps, and the bumps may be electrically connected to the first semiconductor devices formed in the integrated regions 101. The integrated regions 101 may be disposed in the wafer 100 under the first surface 111, and each of the integrated regions 101 may be located to overlap with some of the wafer connection terminals 122. The connection terminals 122 may be formed to protrude from the first surface 111 of the wafer 100. For example, the wafer connection terminals 122 may be formed of, for example but not limited to, copper bumps. In a subsequent process, a thinning process may be applied to the second surface 112 of the wafer 100 to reduce the thickness T1. Thus, no connection terminals are formed on the second surface 112 of the wafer 100.

As mentioned above, at least two of the core dies 200 may be vertically stacked on each of the roof die regions 102 and 103. The core dies 200 may be provided by forming a plurality of second semiconductor devices in a semiconductor wafer and by sawing the semiconductor wafer to separate the plurality of second semiconductor devices from each other. The core dies 200 may be semiconductor dies having substantially the same function and the same shape. Alternatively, the core dies 200 may be provided to include at least two groups of semiconductor dies, and one group of semiconductor dies may have a different function from the other group of semiconductor dies.

In an embodiment, the second semiconductor dies respectively realized in the core dies 200 may be formed to have substantially the same function as the first semiconductor dies respectively realized in the integrated regions 101. For example, the first and second semiconductor dies may be memory devices having substantially the same function. For example, the first and second semiconductor dies may be, for example but not limited to, DRAM devices having substantially the same function. Each of the core dies 200 may be referred to as a DRAM core or a DRAM slice having an HBM structure. Each of the first semiconductor dies integrated in the roof die regions 102 and 103 may also execute the same function as a DRAM core or a DRAM slice having an HBM structure.

Each of the core dies 200 may have a third surface 200-1 corresponding to a bottom side surface, a fourth surface 200-2 corresponding to a topside surface, and vertical sidewalls 200-S connecting the third surface 200-1 to the fourth surface 200-2. Each of the core dies 200 may be, for example but not limited to, a tetragonal chip when viewed from a plan view. First connection terminals 231 may be formed on each of the third surfaces 200-1 of the core dies 200, and second connection terminals 232 may be formed on each of the fourth surfaces 200-2 of the core dies 200. The first and second connection terminals 231 and 232 may provide electrical connection paths for connecting the core dies 200 to external devices. The first and second connection terminals 231 and 232 may be formed of bumps. The first connection terminals 231 may be disposed to vertically overlap with the second connection terminals 232, respectively. The first and second connection terminals 231 and 232 may be disposed to vertically overlap with the wafer connection terminals 122 formed on the core dies 200.

First through vias 250 may be formed to substantially penetrate a body of each of the core dies 200. Each of the first through vias 250 may be formed to provide a path that electrically connects one of the first connection terminals 231 disposed on the third surfaces 200-1 of the core dies 200 to one of the second connection terminals 232 disposed on the fourth surfaces 200-2 of the core dies 200. Each of the first through vias 250 may be located to overlap with one of the first connection terminals 231 and one of the second connection terminals 232. Although not illustrated in the drawings, redistribution lines may be additionally disposed between the first through vias 250 and the first connection terminals 231 or between the first through vias 250 and the second connection terminals 232.

The first through vias 250 may be realized using through silicon vias (TSVs). The wafer connection terminals 122, the first connection terminals 231 and the second connection terminals 232 may be formed of copper bumps, each of which has a diameter of about a few micrometers to about several tens of micrometers and a height of about a few micrometers to about several tens of micrometers. The connection terminals 122, 231, and 232 may be arrayed to have a pitch of about a few micrometers to about several tens of micrometers. A conductive adhesive layer 233 may be disposed on ends of the connection terminals 122, 231, and 232 opposite to the wafer 100 or the core dies 200, and the conductive adhesive layer 233 may be formed to include a solder layer. The solder layer used in formation of the conductive adhesive layer 233 may include an alloy layer of tin (Sn) and silver (Ag). In addition, a barrier layer such as a nickel layer may be disposed between each of the connection terminals 122, 231, and 232 formed of copper bumps and the conductive adhesive layer 233 formed of a solder layer corresponding to a Sn—Ag alloy layer.

The core dies 200 may be disposed on the wafer 100 so that at least two of the core dies 200 are vertically stacked on each of the roof die regions 102 and 103. For example, at least seven of the core dies 200 may be vertically stacked on each of the roof die regions 102 and 103. The core dies 200 stacked on the first roof die region 102 may constitute a first stack structure 291, and the core dies 200 stacked on the second roof die region 103 may constitute a second stack structure 292. If the number of the vertically stacked core dies 200 increases, a storage capacity of the semiconductor package may also increase. Thus, the number of the vertically stacked core dies 200 may increase if the stack structures 291 and 292 are able to maintain a stable state. Since the thickness T1 of the wafer 100 is much greater than the thickness T2 of the core dies 200, the wafer 100 may act as a stable base layer while the core dies 200 are stacked on the wafer 100.

A couple of core dies 200L among the core dies 200 may be disposed side-by-side at a first level on the first roof die region 102 and the second roof die region 103, respectively. The core die 200L on the first roof die region 102 may be located in a first column, and the core die 200L on the second roof die region 102 may be located in a second column. The other core dies 200 may be additionally stacked on the core dies 200L to provide the first and second stack structures 291 and 292.

Two adjacent core dies 200 vertically and immediately stacked from among the core dies 200 may be mechanically and electrically combined with each other by a bump bonding structure 230 including one of the first connection terminals 231, one of the second connection terminals 232, and the conductive adhesive layer 233 between the first and second connection terminals 231 and 232. That is, the second connection terminals 232 disposed on the fourth surface 200-2 of the lower core die 200 may be bonded to the first connection terminals 231 disposed on the third surface 200-1 of the upper core die 200 by the conductive adhesive layer 233. The conductive adhesive layer 233 may include a solder layer, and the solder layer may bond the first connection terminals 231 to the second connection terminals 232 during a reflow process.

The first connection terminals 231L disposed on the third surfaces 200-1 of the core dies 200L and the wafer connection terminals 122 disposed on the first surface 111 of the wafer 100 are bonded to each other by a conductive adhesive layer 233L to provide bonding structures 230L. Accordingly, the bonding structures 230L may bond the wafer 100 to the core dies 200L located at the first level on the wafer 100. The core dies 200 may be vertically stacked on the core dies 200L located at the first level on the wafer 100 to provide the first and second stack structures 291 and 292. The first and second stack structures 291 and 292 may be laterally spaced apart from each other by a gap G1.

A thermos-compression bonding technique using a nonconductive paste (NCP) material (not illustrated) may be employed to stack the core dies 200 and 200L on the wafer 100 and to bond the core dies 200 and 200L to the wafer 100. The NCP material may be introduced into gaps G2 between the core dies 200 and 200L vertically stacked, thereby bonding the core dies 200 and 200L to each other. In addition, the NCP material may also be introduced into gaps between the wafer 100 and the core dies 200L to bond the core dies 200L to the wafer 100. After the core dies 200 and 200L and the wafer 100 are attached to each other using the NCP material, the thermos-compression bonding process may be performed to bond the core dies 200 and 200L to each other and to bond the core dies 200L to the wafer 100.

As illustrated in FIG. 1, a mass reflow process using a flux material may be performed to stack the core dies 200L on the wafer 100 and to stack the core dies 200 on the core dies 200L. In such a case, the flux material may be used to temporarily attach the core dies 200 to each other and to attach the core dies 200L to the wafer 100, and the core dies 200 may be simultaneously bonded to each other by a solder reflow process. During the solder reflow process, the conductive adhesive layer 233, that is, the solder layer may be reflowed to mechanically bond the first connection terminals 231 to the second connection terminals 232.

Since the plurality of core dies 200 are simultaneously bonded to each other by the mass reflow process, the throughput of the bonding process may be improved. In some embodiments, the solder reflow process may be performed whenever the core dies 200 are stacked at each level. In such a case, the solder reflow process may be repeatedly performed two or more times to form the first and second stack structures 291 and 292. Alternatively, according to the mass reflow technique, the solder reflow process may be performed only once after all of the core dies 200 are stacked at all levels. The flux material used in the solder reflow process may be removed by a cleaning process after the solder reflow process.

The flux material may provide an appropriate adhesive strength for the temporary bonding between the solder layers attached to the ends of connection terminals 122, 231, and 232. The temporary bonding between the solder layers may be achieved by a tensile force. Accordingly, the core dies 200 and 200L may be easily aligned with the wafer 100. If the solder reflow process may be performed only once after all of the core dies 200 and 200L are stacked on the wafer 100, the thermal burden on the wafer 100 and the core dies 200 and 200L may be reduced to prevent the degradation of the reliability of the package.

Each of the first and second stack structures 291 and 292 may be formed to include the core dies 200 which are respectively located at least seven different levels (i.e., first to seventh levels) on the wafer 100. The core dies 200 which are vertically stacked in each of the first and second stack structures 291 and 292 may be mechanically bonded to each other by the bonding structures 230. The core dies 200 may include topmost core dies 200T, each of which is located at a topmost level of the first or second stack structure 291 or 292. Each of the topmost core dies 200T may also have a fourth surface 200T-2 which is opposite to the wafer 100, and second connection terminals 232T may be disposed on each of the fourth surfaces 200T-2 of the topmost core dies 200T. The second connection terminals 232T may act as common connection terminals that electrically connect the wafer 100 and the core dies 200 to an external device. That is, the wafer 100 may be electrically connected to an external device through the first through vias 250 and the second connection terminals 232T.

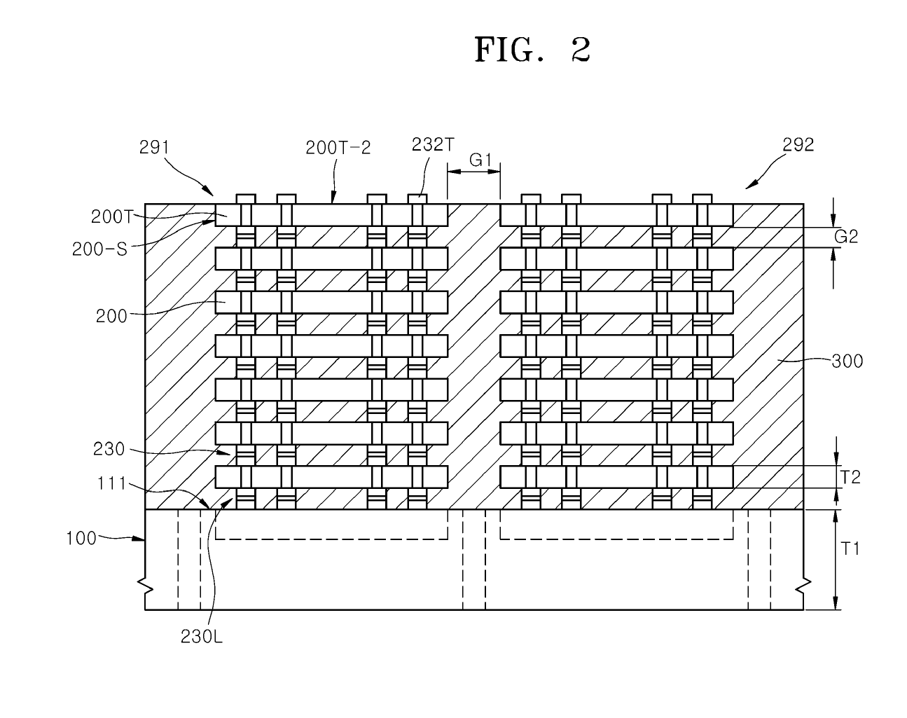

FIG. 2 is a cross-sectional view illustrating a step of forming an underfill layer 300.

Referring to FIG. 2, the underfill layer 300 may be formed to fill the gap G1 between the first and second stack structures 291 and 292 and to cover the first surface 111 of the wafer 100. The underfill layer 300 may be formed on the first surface 111 of the wafer 100 to cover sidewalls of the first and second stack structures 291 and 292. The underfill layer 300 may be formed using a capillary underfill process. While the capillary underfill process is performed, an underfill material may be dispensed onto the first surface 111 of the wafer 100 and may be diffused into the gap G1 between the first and second stack structures 291 and 292 by a capillary phenomenon. In addition, the underfill material dispensed onto the wafer 100 may be diffused to fill the gaps G1 between the core dies 200 as well as between the wafer 100 and the core dies 200L. As a result, the underfill layer 300 filling the gaps G1 and G2 may be formed on the first surface 111 of the wafer 100.

The diffusion of the underfill material may be limited to expose the fourth surfaces 200T-2 of the topmost core dies 200T and the second connection terminals 232T formed on the fourth surfaces 200T-2. Thus, a height of the underfill layer 300 may be controlled to cover the vertical sidewalls 200-S of the core dies 200.

Since the underfill layer 300 is formed to fill the gaps G1 and G2, the bonding structures 230 and 230L may be electrically isolated from each other by the underfill layer 300. In the case of a HBM structural device, several thousand bonding structures may be disposed between two adjacent core dies 200 which are vertically stacked among the core dies 200. While a general-purpose DRAM device requires about one hundred connection terminals, the HBM structural device may require about several thousand bonding structures and about several thousand through vias for a high bandwidth interfacing operation. Accordingly, a distance between the bonding structures 230 in a lateral direction may be within the range of about a few micrometers to about several tens of micrometers.

As described above, if the bonding structures 230 are arrayed to be close to each other, a viscosity of the underfill material should be low so that the underfill material is fully introduced into the gaps G2 by a capillary phenomenon. The underfill material may include a resin component such as silicone resin or epoxy resin. The underfill material may be obtained by dispersing fillers in a resin material. A viscosity of the underfill material may be controlled by changing a kind of the resin component, a content of the resin component, or a ratio of the resin component. Alternatively, a viscosity of the underfill material may also be controlled by changing a size or a content of the fillers contained in the underfill material.

The underfill material having a liquid state may be cured to form the underfill layer 300 having a solid state. The underfill material may be cured using a thermal treatment process. If the underfill material is cured by a thermal treatment process, a volume of the underfill material having a liquid state may be reduced to provide the underfill layer 300 having a solid state. In such a case, a compressive stress may be laterally applied to the underfill layer 300 between the first and second stack structures 291 and 292 due to shrinkage of the underfill material. The compressive stress may cause warpage of the wafer 100.

Since the thickness T1 of the wafer 100 is greater than the thickness T2 of the core dies 200, the wafer 100 may have endurance against the compressive stress of the underfill layer 300. Accordingly, the warpage of the wafer 100 may be suppressed even though the underfill material is cured to form the underfill layer 300.

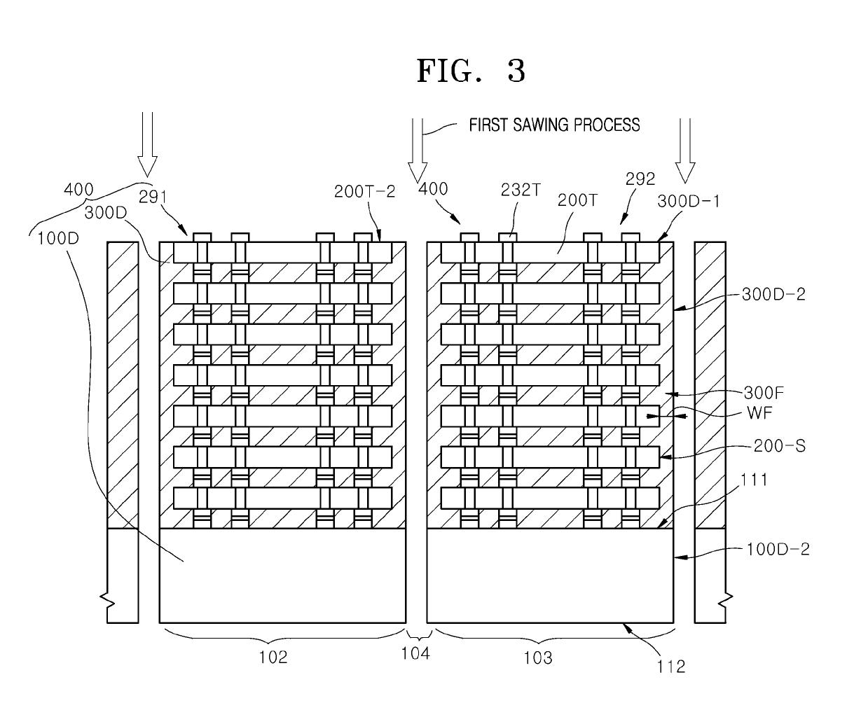

FIG. 3 is a cross-sectional view illustrating a step of sawing the wafer 100 to obtain separate stack cubes 400.

Referring to FIG. 3, a first wafer sawing process may be applied to the wafer 100 and the underfill layer (300 of FIG. 2) to obtain the separate stack cubes 400. The first wafer sawing process may be performed to selectively remove a portion of the underfill layer 300 overlapping with the intermediate region 104 of the wafer 100 and the intermediate region 104 of the wafer 100. That is, the underfill layer 300 between the first and second stack structures 291 and 292 may be removed by the first wafer sawing process. Each of the separate stack cubes 400 may include a roof die 100D corresponding to the roof die region 102 or 103 and the core dies 200 stacked on the roof die 100D.

While the first wafer sawing process is performed, the underfill layer 300 may be separated into a plurality of separate undefill layers 300D. Each of the undefill layers 300D may have vertical sidewalls 300D-2. The sidewalls 300D-2 of the undefill layers 300D may be vertically aligned with sidewalls 100D-2 of the roof dies 100D, respectively. Accordingly, the sidewalls 300D-2 and the sidewalls 100D-2 may constitute vertical sidewalls of the stack cubes 400. Fillet portions 300F of the undefill layers 300D may have a confined width WF. The fillet portions 300F may cover the vertical sidewalls 200-S of the core dies 200.

The width WF of the fillet portions 300F may be confined by the first wafer sawing process for separating the undefill layer 300 into the plurality of undefill layers 300D. That is, the width WF of the fillet portions 300F may be controlled to be uniform and thin by adjusting a width of the removed portion of the undefill layer 300. If the width WF of the fillet portions 300F is reduced, a volume ratio of the fillet portion 300F to the underfill layer 300D may also be reduced.

Topside surfaces 300D-1 of the fillet portions 300F may be located at substantially the same level as the fourth surfaces 200T-2 of the topmost core dies 200T to expose the second connection terminals 232T formed on the fourth surfaces 200T-2 of the topmost core dies 200T. Lower portions of the fillet portions 300F may be in contact with the first surfaces 111 of the roof dies 100D, and the second surfaces 112 of the roof dies 100D may be exposed.

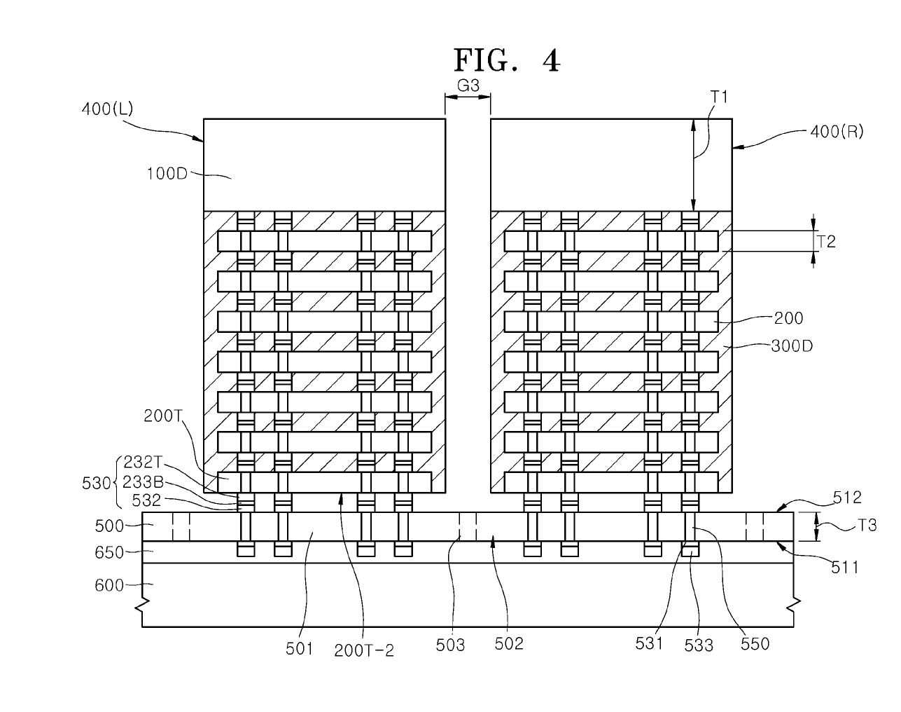

FIG. 4 is a cross-sectional view illustrating the stack cubes 400 stacked on a base die wafer 500.

Referring to FIG. 4, the base die wafer 500 including a plurality of base die regions (e.g., first and second base die regions 501 and 502) may be attached to a carrier 600 using a temporary adhesive layer 650. Each of the first and second base die regions 501 and 502 may correspond to a semiconductor die region in which a third semiconductor device is formed. The base die wafer 500 may be a semiconductor substrate in which the semiconductor die regions are arrayed. An intermediate region 503 may be disposed between the first and second base die regions 501 and 502. The intermediate region 503 may include a scribe lane. The first and second base die regions 501 and 502 may be separated from each other if a die sawing process is performed along the intermediate region 503.

The base die wafer 500 may have a fifth surface 511 to which the carrier 600 attached and a sixth surface 512 on which the stack cubes 400 are stacked. The fifth surface 511 of the base die wafer 500 may correspond to a bottom surface of the base die wafer 500, and the sixth surface 512 of the base die wafer 500 may correspond to a top surface of the base die wafer 500.

Third connection terminals 531 may be disposed on the fifth surface 511 of the base die wafer 500 to electrically connect the base die wafer 500 to an external device. Fourth connection terminals 532 may be disposed on the sixth surface 512 of the base die wafer 500 to electrically connect the base die wafer 500 to the stack cubes 400. The stack cubes 400 may be flipped to be mounted on the base die wafer 500.

The stack cubes 400 may be mounted on the base die wafer 500 so that the fourth surfaces 200T-2 of the topmost core dies 200T face the sixth surface 512 of the base die wafer 500. The fourth connection terminals 532 may be bonded to the second connection terminals 232T disposed on the fourth surfaces 200T-2 of the topmost core dies 200T by a conductive adhesive layer 233B. The fourth connection terminals 532, the second connection terminals 232T, and the conductive adhesive layer 233B between the second and fourth connection terminals 232T and 532 may constitute bonding structures 530. The bonding structures 530 may bond the stack cubes 400 to the base die wafer 500.

The third connection terminals 531 may be disposed on the fifth surface 511 of the base die wafer 500, and the fourth connection terminals 532 may be disposed on the sixth surface 512 of the base die wafer 500 opposite to the third connection terminals 531. Second through vias 550 may penetrate each of the first and second base die regions 501 and 502 to electrically connect the third connection terminals 531 to the fourth connection terminals 532. The second through vias 550 may be realized using through silicon vias (TSVs).

The third and fourth connection terminals 531 and 532 may be disposed to overlap with the second through vias 550. That is, the third and fourth connection terminals 531 and 532 may be vertically aligned with the second through vias 550. Accordingly, the third connection terminals 531 may also be vertically aligned with the fourth connection terminals 532, respectively. The third connection terminals 531, the fourth connection terminals 532 and the second through vias 550 may be disposed to substantially overlap with the second connection terminals 232T. The third connection terminals 531 may be copper bumps protruding from the fifth surface 511 of the base die wafer 500. A conductive adhesive layer 533 may be disposed on ends of the third connection terminals 531 opposite to the base die wafer 500, and the conductive adhesive layer 533 may be formed to include a solder layer.

A thickness T3 corresponding to a distance between the fifth surface 511 and the sixth surface 512 of the base die wafer 500 may be less than the thickness T1 of the roof dies 100D. Since the second through vias 550 are formed to penetrate the base die wafer 500, the thickness T3 of the base die wafer 500 may be set to be substantially equal to the thickness T2 of the core dies 200. In order to stably handle the thin base die wafer 500 having the thickness T3 without transformation such as warpage, the carrier 600 may be attached to the fifth surface 511 of the base die wafer 500 using the temporary adhesive layer 650.

The carrier 600 may be put on a supporter (not illustrated) such as a chuck of an apparatus in which a subsequent process is performed. The carrier 600 may be a quartz wafer of a silicon wafer. The temporary adhesive layer 650 may include an adhesive component for fixing the base die wafer 500 to the carrier 600. The base die wafer 500 may be attached to the carrier 600 so that the third connection terminals 531 and the conductive adhesive layer 533 are embedded in the temporary adhesive layer 650.

The stack cubes 400 including the core dies 200 may be stacked on the base die wafer 500. One of the stack cubes 400 may be flipped to provide a first stack cube 400(L), and the first stack cube 400(L) may be stacked on the first base die region 501 of the base die wafer 500. Similarly, the other one of the stack cubes 400 may be flipped to provide a second stack cube 400(R), and the second stack cube 400(R) may be stacked on the second base die region 502 of the base die wafer 500. The first and second stack cubes 400(L) and 400(R) may be laterally spaced apart from each other by a gap G3. The roof dies 100D of the first and second stack cubes 400(L) and 400(R) may correspond to topmost dies which are located at a topmost level of the first and second stack cubes 400(L) and 400(R), and the base die wafer 500 may be located under the core dies 200 to support the first and second stack cubes 400(L) and 400(R).

The third semiconductor devices formed in the first and second base die regions 501 and 502 may be controllers that control operations of memory devices. For example, if the semiconductor package according to an embodiment is an HBM package, each of the second semiconductor devices of the core dies 200 may be a DRAM device including memory banks in which data are stored, and each of the first semiconductor devices formed in the roof die regions 100D may also be a DRAM device. Each of the third semiconductor devices formed in the first and second base die regions 501 and 502 may include a test circuit for testing various characteristics of the DRAM devices of the core dies 200, a soft repairing circuit, an address circuit, a command circuit and/or a physical layer for signal transmission.

In the event that the stack cubes 400(L) and 400(R) are directly stacked on the base die wafer 500 after the stack cubes 400 are formed, a stress applied to the base die wafer 500 may be significantly reduced while the stack cubes 400(L) and 400(R) are stacked on the base die wafer 500. In contrast, if the core dies 200 are directly stacked on the base die wafer 500 level by level to form the stack cubes 400(L) and 400(R), a stress applied to the base die wafer 500 may relatively increase as compared with a case that the stack cubes 400(L) and 400(R) are directly stacked on the base die wafer 500.

For example, if the core dies 200 are directly and sequentially stacked on the base die wafer 500 to form the stack cubes 400(L) and 400(R), it may be necessary to repeatedly form a number of bonding structures several times. In such a case, a compressive stress applied to the base die wafer 500 may increase to cause damage to the third connection terminals 531 and the conductive adhesive layer 533 which are disposed on the base die wafer 500.

However, if the stack cubes 400(L) and 400(R) are directly stacked on the base die wafer 500, only a single step of forming the bonding structures may be required. Thus, a compressive stress applied to the base die wafer 500 may be significantly reduced to suppress or prevent the third connection terminals 531 and the conductive adhesive layer 533 from being damaged.

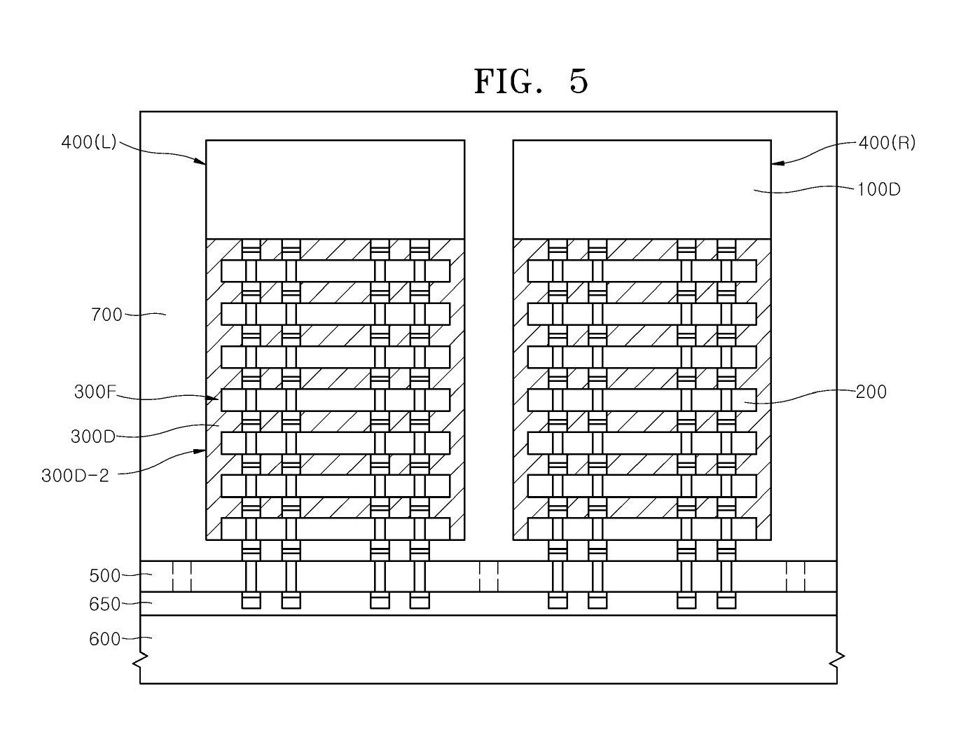

FIG. 5 is a cross-sectional view illustrating a step of forming a mold layer 700.

Referring to FIG. 5, the mold layer 700 may be formed on the base die wafer 500 to fill the gap G3 between the stack cubes 400(L) and 400(R). The mold layer 700 may be formed to cover the stack cubes 400(L) and 400(R) and may be used as a protection layer. That is, the mold layer 700 may be formed to cover the sidewalls 300D-2 of the underfill layer 300D and to cover the roof dies 100D. The mold layer 700 may be formed to encapsulate the stack cubes 400(L) and 400(R). The mold layer 700 may be formed to fill spaces between the base die wafer 500 and the stack cubes 400(L) and 400(R). The mold layer 700 may be formed of a molding material such as an epoxy molding compound (EMC) material. The molding material may include an epoxy material and fillers dispersed in the epoxy material.

A content of the fillers contained in the underfill layer 300D may be lower than that of the fillers contained in the mold layer 700, or no fillers are included in the underfill layer 300D. Thus, the underfill layer 300D may have a thermal expansion coefficient which is higher than a thermal expansion coefficient of the mold layer 700. As a result, the underfill layer 300D may expand or shrink more than the mold layer 700 while the mold layer 700 is formed. Accordingly, it may be necessary to lower a volume ratio of the underfill layer 300D to the mold layer 700 to suppress the thermal expansion or thermal shrinkage of the underfill layer 300D. According to an embodiment, since the fillet portions 300F of the underfill layer 300D is formed to have a confined width, a volume ratio of the fillet portions 300F to the mold layer 700 may be reduced. Thus, the thermal shrinkage or the thermal expansion of the fillet portions 300F may be suppressed to prevent the warpage of the base die wafer 500 while the mold layer 700 is formed.

The underfill layer 300D surrounding the core dies 200 of the first stack cube 400(L) may be separated from the underfill layer 300D surrounding the core dies 200 of the second stack cube 400(R) by the mold layer 700 filling the gap G3. Thus, even though the underfill layers 300D are thermally shrunk or expanded while the mold layer 700 is performed, the thermal shrinkage or the thermal expansion of the underfill layers 300D may not affect the other stack structures adjacent to the first and second stack cubes 400(L) and 400(R) because the mold layer 700 filling the gap G3 acts as a stress buffer. As a result, the warpage of the base die wafer 500 may be more effectively suppressed while the mold layer is performed.

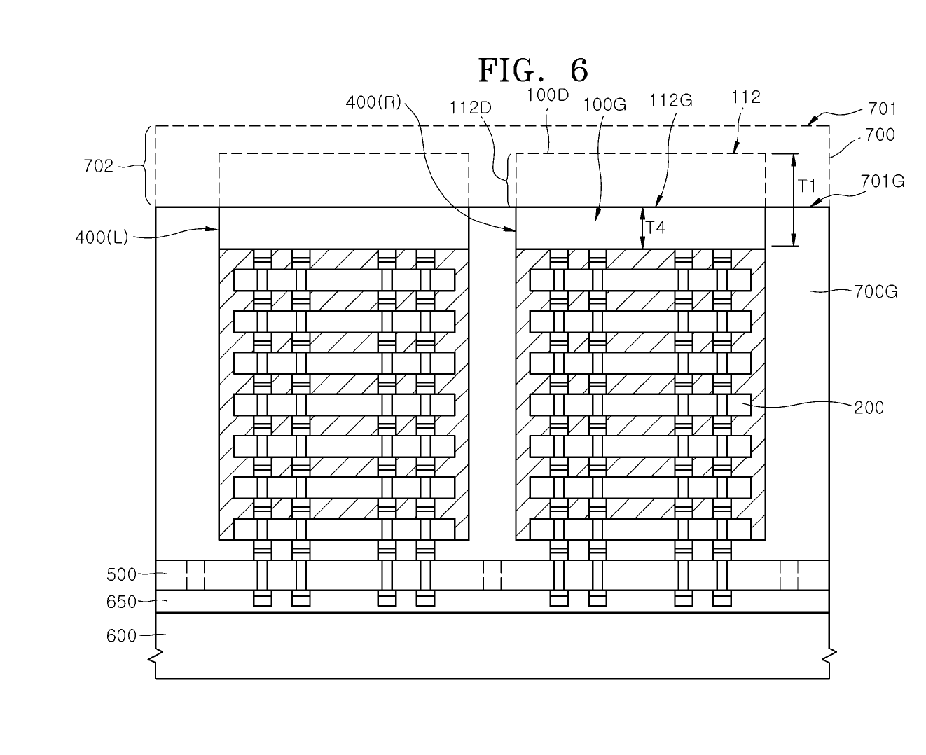

FIG. 6 is a cross-sectional view illustrating a step of removing a portion of the mold layer 700 and a portion of each of the roof dies 100D.

Referring to FIG. 6, a recessing process may be applied to a top surface 701 of the mold layer 700 to remove an upper portion 702 of the mold layer 700. The recessing process may be performed using a grinding process or an etching process. The recessing process may be continuously performed even though the roof dies 100D are exposed. Thus, the recessing process may also be applied to the second surfaces 112 of the roof dies 100D.

Portions 112D of the roof dies 100D may be removed by the recessing process to provide recessed roof dies 100G having recessed surfaces 112G. Thus, the thickness T1 of the roof dies 100D may be reduced by the recessing process, and the recessed roof dies 100G may have a thickness T4 which is less than the thickness T1. If the recessing process terminates, a recessed mold layer 700G having a recessed surface 701G may also be formed. After the mold layer 700 is formed, it may be necessary to reduce the thickness T1 of the roof dies 100D for realization of slim and compact semiconductor packages. Thus, the portions 112D of the roof dies 100D may be removed using the recessing process.

The recessed surface 701G of the recessed mold layer 700G may be coplanar with the recessed surfaces 112G of the recessed roof dies 100G. That is, the recessed surface 701G of the recessed mold layer 700G and the recessed surfaces 112G of the recessed roof dies 100G may be located at substantially the same level. Since the core dies 200 in each of the first and second stack cubes 400(L) and 400(R) are vertically stacked, it may be necessary to efficiently emit or radiate the heat generated by the core dies 200. Accordingly, the recessed roof dies 100G exposed by the recessing process may be very helpful to emit the heat generated by the core dies 200 while the core dies 200 operate.

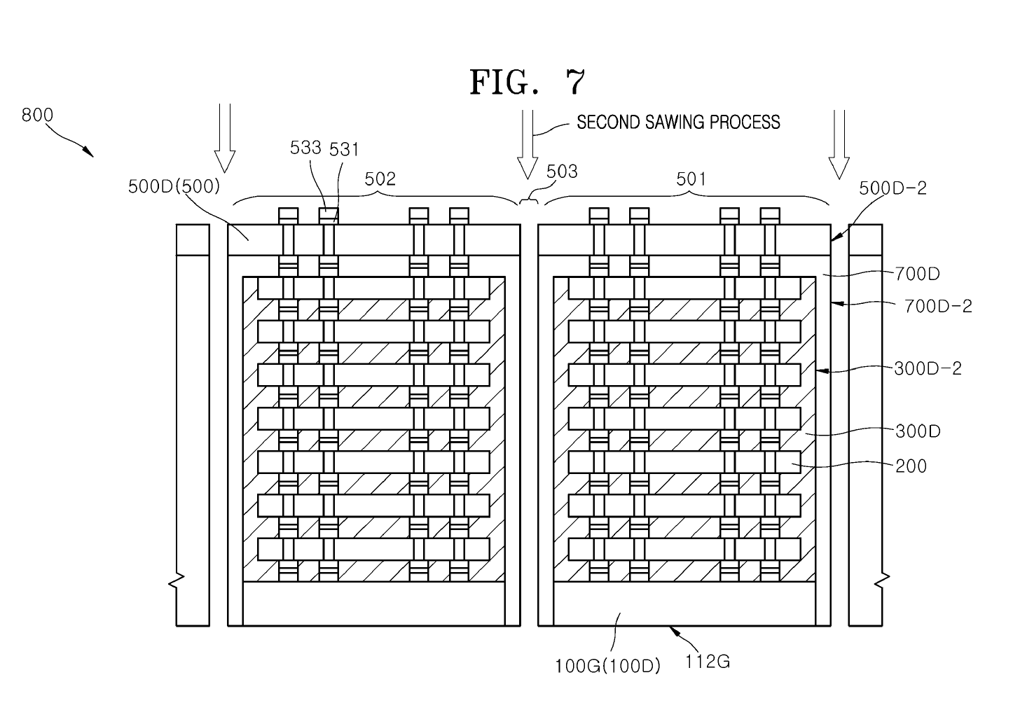

FIG. 7 is a cross-sectional view illustrating a step of forming separate semiconductor packages 800.

Referring to FIG. 7, the carrier (600 of FIG. 6) may be detached from the base die wafer (500 of FIG. 6). The temporary adhesive layer 350 and the carrier 600 may be removed from the base die wafer 500 to expose the third connection terminals 531 and the conductive adhesive layer 533 disposed on the base die wafer 500. The stack cubes 400 may be electrically tested using the exposed third connection terminals 531 as input/output terminals of the stack cubes 400.

The stack cubes 400 may be separated from each other by a second wafer sawing process to provide separate semiconductor packages 800. The second wafer sawing process may be performed by cutting the base die wafer 500 along a scribe lane corresponding to the intermediate region 503 of the base die wafer 500 to provide the semiconductor packages 800. Each of the semiconductor packages 800 may be provided to include a single base die 500D having the first base die region 501 or the second base die region 502 and the core dies 200 vertically stacked on a surface of the base die 500D. The second wafer sawing process for providing the separate semiconductor packages 800 may be performed by removing the intermediate region 503 of the base die wafer 500 and a portion of the recessed mold layer 700G overlapping with the intermediate region 503.

Sidewalls 700D-2 of mold layers 700D separated by the second wafer sawing process may be vertically aligned with sidewalls 500D-2 of the base dies 500D. The sidewalls 700D-2 of the mold layers 700D may have substantially the same vertical profile as the sidewalls 300D-2 of the underfill layers 300D. Accordingly, sidewalls of the core dies 200 may be protected by a double layered structure comprised of the underfill layer 300D and the mold layer 700D.

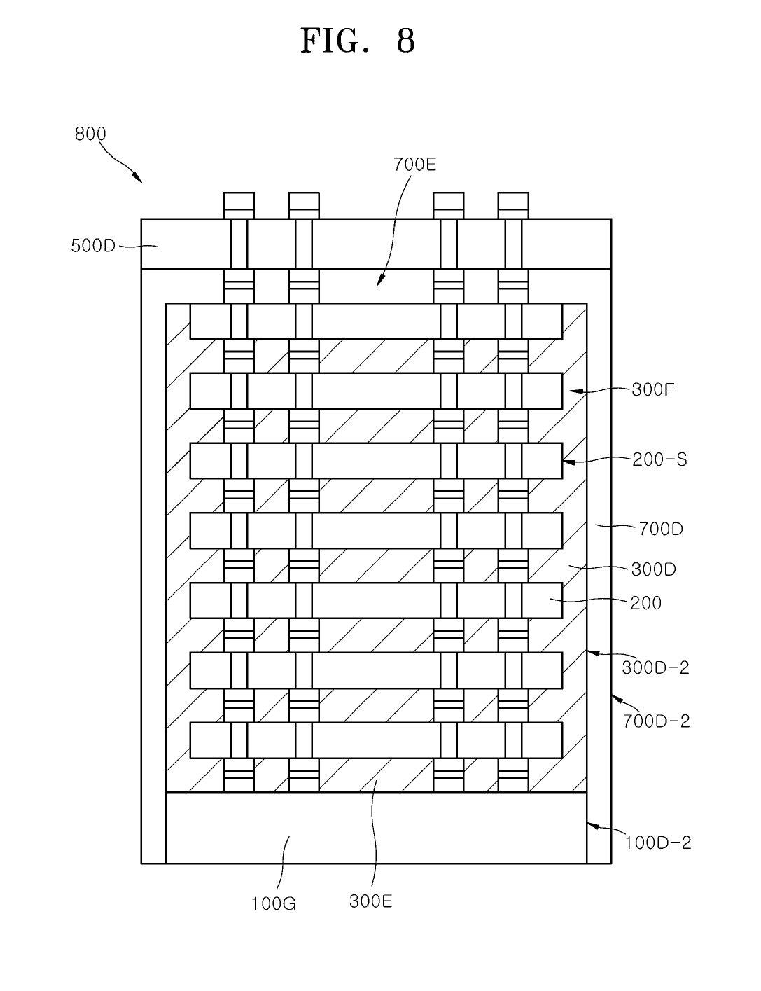

FIG. 8 is a cross-sectional view illustrating one of the separate semiconductor packages 800 described with reference to FIG. 7.

Referring to FIG. 8, the semiconductor package 800 may include the base die 500D and the core dies 200 vertically stacked on a surface of the base die 500D. The semiconductor package 800 may further include the roof die 100G stacked on a surface of a stack structure of the core dies 200. The core dies 200 may be disposed between the base die 500D and the roof die 100G. Spaces between the core dies 200 may be filled with the underfill layer 300D, and the underfill layer 300D may extend to provide the fillet portion 300F covering the sidewalls 200-S of the core dies 200. The underfill layer 300D may have the sidewalls 300D-2 with a vertical profile. The roof die 100G may also have the vertical sidewalls 100D-2 which are vertically aligned with the sidewalls 300D-2 of the underfill layer 300D. The sidewalls 100D-2 of the roof die 100G and the sidewalls 300D-2 of the underfill layer 300D may be covered with the mold layer 700D. The mold layer 700D may also have the vertical sidewalls 700D-2 like the underfill layer 300D. It may be forbidden that the underfill layer 300D extends to fill a space between the base die 500D and the core die 200 adjacent to the base die 500D, but the underfill layer 300D may include an extension 300E filling a space between the roof die 100G and the core die 200 adjacent to the roof die 100G. The mold layer 700D may also include an extension 700E filling a space between the base die 500D and the core die 200 adjacent to the base die 500D.

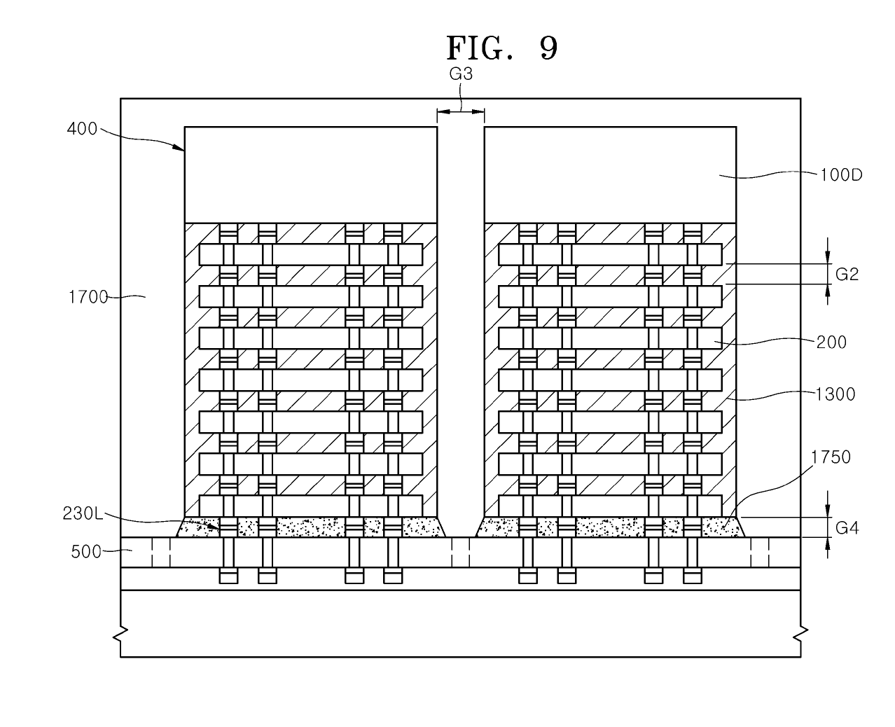

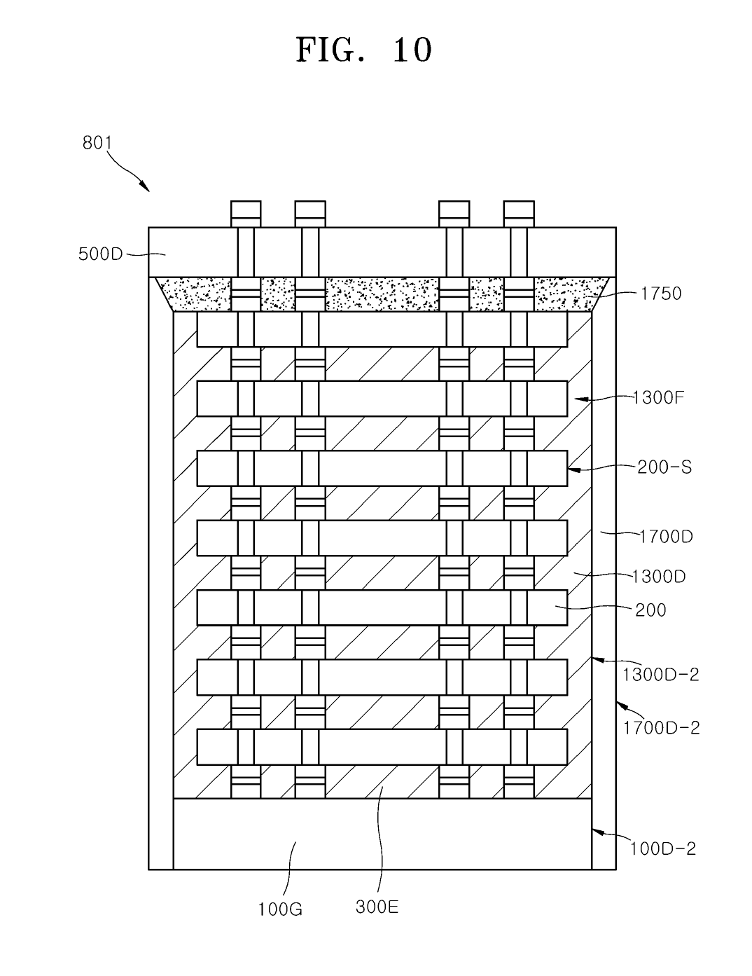

FIGS. 9 is a cross-sectional view illustrating a method of fabricating semiconductor packages according to an embodiment, and FIG. 10 is a cross-sectional view illustrating one of the semiconductor packages manufactured by the fabrication method described with reference to FIG. 9.

FIG. 9 is a cross-sectional view illustrating a step of forming a second underfill layer 1750 and a mold layer 1700.

Referring to FIG. 9, stack cubes 400 including first underfill layers 1300 may be provided. The first underfill layers 1300 may correspond to the underfill layers 300D which are described in the previous embodiments. After the stack cubes 400 are stacked on the base die wafer 500, the second underfill layer 1750 may be formed to fill a gap G4 between the base die wafer 500 and each of the stack cubes 400. The second underfill layer 1750 may be formed using substantially the same manner as used in formation of the first underfill layers 1300. The second underfill layer 1750 may be formed using a capillary underfill process. While the capillary underfill process is performed, an underfill material may be dispensed onto the base die wafer 500 and may be diffused into the gap G4 between the base die wafer 500 and each of the stack cubes 400 by a capillary phenomenon.

In case of a HBM structural device, several thousand bonding structures may be disposed between the base die wafer 500 and each of the stack cubes 400. While a general-purpose DRAM device requires about one hundred connection terminals, the HBM structural device may require about several thousand bonding structures and about several thousand through vias for a high bandwidth interfacing operation. Accordingly, a distance between the bonding structures 230L in a lateral direction may be within the range of about a few micrometers to about several tens of micrometers.

As described above, if the bonding structures 230L are arrayed to be close to each other, a viscosity of the underfill material used in formation of the second underfill layers 1750 should be low so that the underfill material is fully introduced into the gaps G4 by a capillary phenomenon. The underfill material may include a resin component such as silicone resin or epoxy resin. The underfill material may be obtained by dispersing fillers in a resin material. A viscosity of the underfill material may be controlled by changing a kind of the resin component, a content of the resin component, or a ratio of the resin component. Alternatively, a viscosity of the underfill material may also be controlled by changing a size or a content of the fillers contained in the underfill material. The underfill material having a liquid state may be cured to form the second underfill layers 1750 having a solid state.

A mold layer 1700 may be formed to fill the gap G3 between the stack cubes 400. The mold layer 1700 may be formed on a surface of the base die wafer 500 to cover the stack cubes 400. The mold layer 1700 may be formed to be in contact with sidewalls of the second underfill layers 1750. The mold layer 1700 may be formed to encapsulate the stack cubes 400.

The mold layer 1700 may not extend into the space between the base die wafer 500 and each of the stack cubes 400 due to the presence of the second underfill layers 1750. The mold layer 1700 may be formed of a molding material such as an epoxy molding compound (EMC) material. The molding material may include an epoxy material and fillers dispersed in the epoxy material. A content of the fillers contained in the second underfill layer 1750 may be lower than that of the fillers contained in the mold layer 1700, or no fillers are included in the second underfill layer 1750. Thus, since the second underfill layer 1750 has a fluidity which is relatively higher than a fluidity of the mold layer 1700, the gap G4 between the base die wafer 500 and each of the stack cubes 400 may be fully filled with the second underfill layer 1750 by a capillary phenomenon. In order to fill the gap G4 with the mold layer 1700 instead of the second underfill layer 1750, a fluidity of the molding material used in formation of the mold layer 1700 has to be relatively high. That is, a content of the fillers contained in the molding material has to be relatively low to fill the gaps G4 with the mold layer 1700. However, according to a present embodiment, it may be unnecessary to fill the gaps G4 with the mold layer 1700 because of the presence of the second underfill layer 1750. Accordingly, a content of the fillers contained in the mold layer 1700 may be relatively higher than a content of the fillers contained in the second underfill layer 1750.

After the mold layer 1700 is formed, the mold layer 1700 may be recessed. Subsequently, a wafer sawing process may be applied to the base die wafer 500 and the mold layer 1700 to provide separate semiconductor packages 801, one of which is illustrated in FIG. 10.

Referring to FIG. 10, the semiconductor package 801 may include the base die 500D and a stack structure of the core dies 200 vertically stacked on a surface of the base die 500D. The semiconductor package 800 may further include the roof die 100G stacked on a surface of the stack structure of the core dies 200. The core dies 200 may be disposed between the base die 500D and the roof die 100G. Spaces between the core dies 200 may be filled with the first underfill layer 1300D, and the first underfill layer 1300D may extend to provide a fillet portion 1300F covering the sidewalls 200-S of the core dies 200. The first underfill layer 1300D may have sidewalls 1300D-2 with a vertical profile. The roof die 100G may also have the vertical sidewalls 100D-2 which are vertically aligned with the sidewalls 1300D-2 of the first underfill layer 1300D. The sidewalls 100D-2 of the roof die 100G and the sidewalls 1300D-2 of the first underfill layer 1300D may be covered with the mold layer 1700D. The mold layer 1700D may also have vertical sidewalls 1700D-2 like the first underfill layer 1300D. It may be forbidden that the first underfill layer 1300D extends to fill a space between the base die 500D and the core die 200 adjacent to the base die 500D, but the first underfill layer 1300D may include the extension 300E filling a space between the roof die 100G and the core die 200 adjacent to the roof die 100G. A space between the base die 500D and the core die 200 adjacent to the base die 500D may be filled with the second underfill layer 1750. The mold layer 1700D may not extend into the space between the base die 500D and the core die 200 adjacent to the base die 500D because of the presence of the second underfill layer 1750.

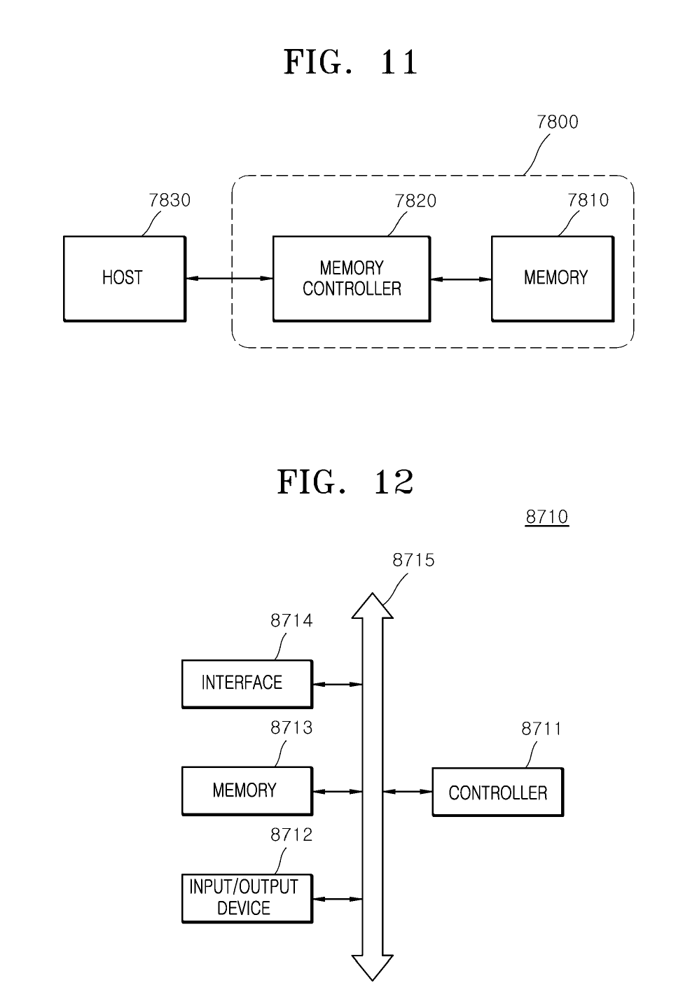

FIG. 11 is a block diagram illustrating an electronic system including a memory card 7800 including at least one semiconductor package according to an embodiment. The memory card 7800 includes a memory 7810 such as a nonvolatile memory device, and a memory controller 7820. The memory 7810 may receive a command from the memory controller 7820 to store data therein or to output out stored data. The memory 7810 and/or the memory controller 7820 may include at least one of the semiconductor packages according to the embodiments.

The memory 7810 may include a nonvolatile memory device to which the technology of the embodiments of the present disclosure is applied. The memory controller 7820 may control the memory 7810 such that data stored in the memory 7810 are read out or data are stored in the memory 7810 in response to a read/write request from a host 7830.

FIG. 12 is a block diagram illustrating an electronic system 8710 including at least one package according to an embodiment. The electronic system 8710 may include a controller 8711, an input/output device 8712, and a memory 8713. The controller 8711, the input/output device 8712 and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include one or more of the semiconductor packages according to the embodiments of the present disclosure. The input/output device 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is an equipment capable of performing wireless communication, the electronic system 8710 may be used in a communication system such as of CDMA (code division multiple access), GSM (global system for mobile communications), NADC (north American digital cellular), E-TDMA (enhanced-time division multiple access), WCDAM (wideband code division multiple access), CDMA2000, LTE (long term evolution) and Wibro (wireless broadband Internet).

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor package comprising:
a plurality of core dies vertically stacked on a base die;
a roof die stacked on a stack structure including the plurality of core dies;
an underfill layer pattern filling spaces between the core dies and including a fillet portion covering sidewalls of the core dies, wherein the underfill layer pattern has vertical sidewalls which are aligned with sidewalls of the roof die; and
a mold layer pattern covering the sidewalls of the underfill layer pattern and the roof die,
wherein the mold layer pattern has sidewalls, and the sidewalls of the mold layer pattern and the underfill layer pattern have substantially the same vertical profile.

2. The semiconductor package of claim 1, wherein the mold layer pattern is disposed to expose a surface of the roof die opposite to the core dies.

3. The semiconductor package of claim 1, wherein the roof die has a thickness which is greater than a thickness of the core dies and a thickness of the base die.

4. The semiconductor package of claim 1,
wherein the base die includes a third semiconductor device configured for controlling semiconductor devices formed in the core dies and the roof die.

5. The semiconductor package of claim 1, wherein the core dies, the roof die, and the base die are bonded to each other using bonding structures.

6. The semiconductor package of claim 5, wherein each of the core dies includes through vias which are connected to the bonding structures.

7. The semiconductor package of claim 1, further comprising wafer connection terminals disposed on a surface of the roof die that faces the core dies,
wherein the wafer connection terminals electrically connect the roof die to the core dies.

8. The semiconductor package of claim 1, wherein the mold layer includes an extension filling a space between the base die and the core die adjacent to the base die.

9. The semiconductor package of claim 1,
wherein that the underfill layer is prevented from extending into a space between the base die and the core die adjacent to the base die; and
wherein the underfill layer includes an extension filling a space between the roof die and the core die adjacent to the roof die.

10. The semiconductor package of claim 1, wherein a content of fillers contained in the underfill layer is less than a content of fillers contained in the mold layer.

11. The semiconductor package of claim 1, wherein the underfill layer is comprised of an underfill material without any filler.

12. A semiconductor package comprising:
a plurality of core dies vertically stacked on a base die;
a roof die stacked on a stack structure including the plurality of core dies;
a first underfill layer pattern filling spaces between the core dies and including a fillet portion covering sidewalls of the core dies, wherein the first underfill layer pattern has vertical sidewalls which are aligned with sidewalls of the roof die;
a second underfill layer filling a space between the base die and the core die adjacent to the base die; and
a mold layer pattern covering the sidewalls of the first underfill layer pattern, sidewalls of the second underfill layer, and the sidewalls of the roof die,
wherein the mold layer pattern has sidewalls, and the sidewalls of the mold layer pattern and the sidewalls of the first underfill layer pattern have substantially the same vertical profile.

13. The semiconductor package of claim 12, wherein the content of fillers contained in the mold layer is greater than a content of fillers contained in the second underfill layer.

14. The semiconductor package of claim 12, wherein a content of fillers contained in the first underfill layer is less than a content of fillers contained in the mold layer.

15. The semiconductor package of claim 12, wherein the first underfill layer is comprised of an underfill material without any filler.

16. The semiconductor package of claim 12, wherein the second underfill layer is comprised of an underfill material without any filler.
